(19) United States
(12) Patent Application Publication
(10) Pub. No.: US 2002/0027962 A1
(43) Pub. Date: Mar. 7, 2002

(54) Device and method for porcessing frequency signals

(76) Inventors: Jorg-Martin Muller, Stuttgart (DE); Holger Helmke, Backnang (DE)

Correspondence Address: Kirschstein, Ottinger, Israel & Schiffmiller, P.C., 489 Fifth Avenue, New York, NY, 10017-6105, US

(21) Appl. No.: 09/886,944

(22) Filed: Jun. 21, 2001

(30) Foreign Application Priority Data
Jun. 21, 2000 (DE) P.10030583.0

(51) Int. Cl. H03H 7/30; H04L 27/06; H04L 27/14; H04L 27/22

(52) U.S. Cl. 375/316; 375/229

(57) ABSTRACT

The invention concerns a device for processing frequency signals with a power limiter (10), in which the power limiter (10) has a first signal path (12), the power limiter (10) has a second signal path (14), the first signal path (12) has means (16) for analog signal processing, the second signal path (14) has means (18) for digital signal processing, the means (18) for digital signal processing have means for selective suppression of specific frequency regions and an output of the first signal path (12) and an output of the second signal path (14) are connected to means (22) for combination of signals. The invention also concerns a method that can advantageously be executed with the device according to the invention.

The present invention concerns a device for processing frequency signals with a power limiter. The invention also concerns a process for processing frequency signals, in which power is limited.

### PRIOR ART

Digital multipoint systems (DMS) are known in the field of modem radio systems. A DMS frequency band consists of a number of frequency channels. For example, 32 channels, each with 28 MHz, exist in a DMS-26 GHz. A DMS operator generally obtains permission from the regulatory authority to offer his services in one or more connected or non-connected channels. The manufacturer must therefore tune the radio frequency modules (RF) of the base station and subscriber apparatus to these channels during production. This leads to high development costs, since several channel-specific RF modules must be developed. Increased expense is also incurred during production, for example, because of the increased stock-keeping costs, since each channel requires specific components.

The conventional broadband scanning is described below. At a stipulated resolution or dynamics of the analog-digital converters employed in the system, the upline analog filters are to be laid out so that saturation of the converters is avoided even in extreme operating conditions (worst case). Since the quantization noise power density of an analog-digital converter is constant, attenuation of the analog signal to avoid saturation is not possible without a significant deterioration in the signal-to-noise ration (SNR) of the useful channel. There is a hazard in broadband scanning that frequency fractions from foreign systems are also converted, on whose power density no influence can be had. This is the case in a DMS system, for example, when an adjacent channel belongs to another operator.

FIG. 11 shows a scenario for the worst case power density distribution at the input of a broadband analog-digital converter in a DMS system. The power density p is plotted versus frequency f in the diagram. The channel of interest (COI) is situated in the center of the power density distribution. It is assumed in the context of this discussion that all adjacent channels lie at the input of the analog-digital converter with a constant power density of BNR (dB) (blocking-to-noise ratio) and the useful channel with a power density of SNR (dB) (signal-to-noise ratio) above the noise level of the analog processing chain. The power density of the adjacent channels can then lie up to 30 dB above the useful channel if these channels belong to another operator. The following therefore applies in the worst case:

BNRₘₐₓ=SNR+30 dB (1)

By calculation of the total power from the model according to FIG. 11 and the requirement that this power must be smaller than the peak power of an analog-digital converter with an effective resolution of ADC bit, a condition can be derived for the maximum BNR, for which the converter is still not operated in saturation:

$$B N R \leq 10 \cdot 1 g ( \frac{3 \cdot {2}^{2 ( ADC - 1 )} \cdot {10}^{\frac{C r + N Q R}{10}} - \frac{{W}_{CH}}{{f}_{s}} \cdot {10}^{\frac{S N R}{10}} + \frac{2 \cdot {W}_{F} + W}{{f}_{s}} - \frac{1}{2}}{\frac{{W}_{F} + W - {W}_{CH}}{{f}_{s}}} ) \qquad ( 2 )$$

where

SNR=signal-to-noise ratio of the useful channel in dB

BNR=blocking-to-noise ratio of the adjacent channel in dB

CR=crest factor in dB

NQR=distance between the quantization noise power density Q and the signal noise power density in dB

f_{S}=scanning frequency

ADC=number of effective bits of the analog digital converter

W_{CH}=bandwidth of a useful channel

W=total useful bandwidth at the input of the analog-digital converter

W_{F}=bandwidth of the filter flanks of the analog anti-aliasing filter

The above equation (2) is explained with reference to 2 examples.

### EXAMPLE 1

Conversion of 2 Channels in a 26 GHz System is Described

The channel pattern is W_{CH}=28 MHz. Two of these channels are to be processed simultaneously with an analog digital converter (W=56 MHz). The scanning frequency is f_{S}≅200 MHz. The maximum occurring SNR of the useful channel lies at SNR≅17 dB. A converter with an effective number of bits with ADC=9 is assumed as analog-digital converter. The transition bandwidth of the analog filter is W_{F}=0.25 W=14 MHz. The crest factor (input peak amplitude to average amplitude) is assumed at CR=10 dB.

It is additionally to be required that the maximum admissible SNR degradation should be Δ=0.5 dB owing to analog-digital conversion. From this, we obtain the spacing of the quantization noise power and signal noise power density at

$$N Q R = - 10 \cdot 1 g ( {10}^{\frac{Δ}{10}} + 1 ) \approx 9 dB \qquad ( 3 )$$

According to equation (3), we get a maximum admissible BNR of

BNR<41 dB (required: BNR=47 dB)

The power density of the adjacent channel must therefore lie 24 dB above the power density of the useful channel. The 30 dB requirement therefore cannot be maintained and, under unfavorable conditions, overriding of the converter can occur, so that a dynamic reduction by channel-specific analog prefilters becomes necessary.

### EXAMPLE 2

Conversion of Four Channels at DMS-26 GHz is Described

Four channels are now processed with an analog-digital converter (W=122 MHz) at a channel pattern of W_{CH}=28 MHz. The scanning frequency is to be f_{S}≅200 MHz. The maximum occurring SNR of the useful channel is assumed at SNR=17 dB, as above. A converter with ADC=7 is assumed as analog digital converter. The transition bandwidth of the analog filter is W_{F}=0.25 W=28 MHz. The crest factor is Cr=10 dB.

At an admissible SNR degradation owing to analog-digital conversion of Δ=0.5 dB, we therefore obtain from the above equation a maximum admissible BNR of

BNR<27 dB (required: BNR=47 dB) (4)

The power density of the three adjacent channels must therefore lie only 10 dB above the power density of the useful channel. This conventional solution is therefore completely unsuitable for use in DMS. In order to be able to fulfill the 30 dB requirement with a margin, a 400 MHz analog-digital converter with an effective resolution of 12 bit (about 14 bit nominal) would have to be available, which is not presently foreseeable (1998). In order to avoid overriding of the converter, the signal power has to be reduced by at least 20 dB.

The maximum load scenario was just described. In addition to this, the minimum load scenario must also be investigated. FIG. 12 is referred to for this purpose. In this case, only the signal power of a traffic channel (subchannel) is present at the input of the converter, with a bandwidth of, say, 80 kHz (DMS) and an SNR of 5 dB (QPSK), so that the converter can barely be modulated at all. Together with the very high overscanning factor (scanning frequency/useful channel bandwidth), this produces a strong correlation of the signal and quantization noise and therefore a significant deterioration of SNR.

This effect can be countered by increasing the input power, for example, by an automatic gain control (AGC). Conditions for white quantization noise can be given analytically and by simulations.

The bandwidth relevant for the overscanning factor is based on the broadband analog preprocessing and therefore the large noise bandwidth Wₙₒᵢₛₑ=W.

The overscanning factor for Examples 1 and 2 is therefore:

$$η = \frac{{f}_{s}}{W} \approx {2}^{2} \qquad ( 5 )$$

The results show that, during fulfillment of the condition

$$10 \cdot 1 g ( \frac{{σ}^{2}}{{δ}^{2}} ) = 10 \cdot 1 g ( \frac{1}{6} \cdot {10}^{\frac{N Q R + A G C}{10}} ) > 0 dB \qquad ( 6 )$$

the quantization noise for these overscanning factors is approximately white. σ² denotes the average signal power and δ the quantization step width of the employed converter.

The following condition is therefore obtained:

AGC>8 dB−NQR (7)

At an NQR of more than 8 dB, which will certainly always be the case, an AGC is therefore unnecessary.

An important parameter for laying out the scanning system is the admissible deviation of the scanning time from its nominal value (scanning jitter). The model according to FIG. 13 is referred to in order to quantitatively determine the variance of the timing jitter. In the context of this model, it is assumed that the jitter noise power, which is produced, for example, by a channel, is spectrally limited to it.

The following equation gives a condition for the variance of the timing jitter as a function of the resolution of the employed converter, the useful channel bandwidth and the required spacing between the quantization and jitter noise power density.

$$Δ = 10 \cdot 1 g ( {10}^{\frac{S J R - S N R}{10}} + {10}^{\frac{N Q R}{10}} + 1 ) = 10 \cdot 1 g ( {10}^{\frac{N Q R}{10}} \cdot ( {10}^{\frac{Q J R}{10}} + 1 ) + 1 ) \qquad ( 8 )$$

where

SJR=−20 . lg(2 . π. fₘₐₓ . σⱼ)

and

σⱼ=variance of the jitter of the scanning cycle in sec

SNR=signal-to-noise ratio of the useful channel in dB

NQR=spacing between signal and quantization noise power density in dB

QJR=spacing between quantization and jitter noise power density in dB

SJR=spacing between signal and timing jitter noise power density in dB

fₘₐₓ=maximum signal frequency

The requirements on the variance of the timing jitter are explained below by two examples.

### EXAMPLE 1

Conversion of Two Channels at 26 GHz is Described

The most stringent condition applies for the second 28 MHz channel, i.e., fₘₐₓ=68 MHz. In order for the first term in the internal parentheses of equation 2 to make no significant contribution to SNR degradation, the following is required:

QJR>10 dB (9)

With SNR=17 dB and NQR=9 dB, a requirement on the jitter of

σ_{J}≦37 psec (10)

is obtained.

### EXAMPLE 2

Conversion of Four Channels at 26 GHz is Considered

The most stringent condition applies for the fourth 28 MHz channel, i.e., fₘₐₓ=136 MHz.

With the figures from Example 1, we obtain the requirement:

σ_{J}≦18.5 psec (11)

The aforementioned comments demonstrate that, during conventional broadband scanning (for example, four 28 MHz channels at 26 GHz), an analog-digital converter with an effective resolution of at least 12 bit (14 bit nominal) at a scanning frequency of more than 400 MHz is required. Only with such converter dynamics are the signal powers of foreign systems received in adjacent channels manageable. The availability of such converters appears to be ruled out in the foreseeable future.

In order to be able to perform broadband scanning with present converters, the signal must be limited in its power before conversion. This can ordinarily occur by channel-specific analog filters, which, however, entails the already mentioned problem that the filters must be laid out channel-specifically.

### ADVANTAGES OF THE INVENTION

The invention is based on the prior art according to claim 1, in that the power limiter has a first signal path, that the power limiter has a second signal path, that the first signal path has means for analog signal processing, that the second signal path has means for digital signal processing, that the means for digital signal processing have means for selective suppression of specific frequency regions, and that an output of the first signal path and an output of the second signal path are connected to means for combination of the signals. It is possible with this arrangement to reduce the power in all channels adjacent to the useful channel. This arrangement is configured and controlled by the digital part, with which it is adaptable to the useful channel being processed. In the present context, useful channel is understood to mean the entire frequency range to be processed in a base station. In 26 GHz systems, this could be, for example, one or more adjacent or non-adjacent 28 MHz channels.

The second signal path preferably has an analog-digital converter, an FIR filter (finite impulse response) and a digital-analog converter. In this manner, a causal complementary filter is available through the power limitation module, whose filter part is designed digitally. In the second signal path, the useful channel is suppressed by means of an FIR filter, while the adjacent channels are processed with the highest possible SNR. The filter signal is then fed for further processing to a digital-analog converter.

A power adjustment, a delay adjustment and an si(x) compensator are preferable performable in the FIR filter. Consequently, the digital signal can be processed so that a signal is subsequently produced by combination with the analog signal supplied via the first signal path, in which the useful band is transmitted unaltered, while the adjacent channels are suppressed.

It is advantageous in this context that the FIR filter has steep filter flanks. Because of this, it is possible to efficiently suppress the signal power right next to the useful channel, which leads to a high degree (N>150).

It is preferred that the FIR filter operate at the scanning rate of the converter. It can also be operated without a scanning rate reduction.

It can be useful for the FIR filter to be implemented by means of a filter bank. One therefore operates with several analysis filters, in which each processes a band-pass FIR filter for one channel; the scanning rate is simultaneously reduced. With four analysis filters, each of the filters operates at one-fourth of the scanning rate. The desired band-stop characteristics are produced by tuning out the sub-band of the useful channel. The other sub-bands can be processed for the subsequent synthesis filtering. After synthesis filtering, an addition of the sub-band signals with the high scanning frequency can occur.

The first signal path preferably has an analog delay element. Because of this, a situation is achieved in which the delay on the first signal path and second signal path coincide, so that a reduction in filter effect is avoided.

It is particularly preferred if the analog delay element have a constant group delay. This constancy of group delay over a frequency range between, say, 20 and 150 MHz, permits a good filter effect over the mentioned large frequency range. A realistic constant group delay, for example, lies in the region of 250 ns.

It is particularly preferred that the constant group delay of the total delay of the converter and the FIR filter of the second signal path correspond. The delay of the analog delay element is therefore adapted to the delay of the second signal path.

The means for combining signals preferably has an analog adder. With this type of device, signals of the two signal paths can be subtracted from each other, so that the resulting signal has an almost unaltered useful band, while the adjacent channels are suppressed.

The output signal of the analog adder can preferably be fed to an analog-digital converter module. Actual analog-digital conversion therefore occurs based on an input signal, in which the interfering adjacent channels are suppressed.

It is useful if the input frequency signal can be fed to means for analog preprocessing. In this manner, the analog input signal can be attenuated by the analog preprocessing so that the converter is not overridden on the second signal path. This is advantageous, since noise develops from the converter on the second signal path, which is uncorrelated with the original signal and therefore cannot be suppressed either. The power density of this noise contribution must consequently be as small as possible (high SNR of the adjacent channel).

A calibration signal can preferably be fed to the input frequency signal. This calibration signal, which lies “outside” of the useful signal, is evaluated in the digital part (modem) behind the analog-digital converter module. Control of the digital delay can occur on this basis, so that suppression of the calibration signal is maximal. Since there is a possibility of adjusting the delay adaptively in the digital part, for example, by inclusion of delay elements, there is no need for the analog part to absolutely adjust the delay. As long as this lies merely on the same order, it is possible to tune the first signal path and the second signal path to each other. However, it should be kept in mind that the group delay of the analog delay is constant over the entire frequency range of interest.

In another variant, it can be advantageous to provide a third signal path that digitally implements an equivalent channel, in which a scanning rate reduction occurs, the third signal path having a complex mixer and an FIR filter. In this manner, band-stop filtering of the useful band in the second signal path can be dispensed with. The filter requirements on the FIR filter can be drastically reduced in this way. It is therefore sufficient that the analog delay element implement an only much smaller delay that lies by a factor of 16 lower than in the variant with band-stop filtering. The FIR filter in the second signal path therefore carries out only an si(x) compensation, a delay adjustment and a power adjustment.

The output signal of the analog-digital converter module can preferably be fed to a fourth signal path, in which a scanning rate reduction occurs, the fourth signal path having a complex mixer and an FIR filter. The output signal of the analog-digital converter module is therefore adapted to the signal of the third signal path.

It is then advantageous in this context if an output of the third signal path and an output of the fourth signal path are connected to means for combining the signals. By the transition to an equivalent complex low-pass signal and subsequent combination of the signals of the third signal path and the fourth signal path, a scanning rate reduction can therefore be performed, for example, by a factor of 8.

It can be useful for the output signal of the analog-digital converter module to be fed back to at least one FIR filter via a calibration unit. The effects of the corresponding FIR filter can therefore be adjusted based on the output signal of the analog-digital converter module.

It can likewise be useful in the same context for the output signal of the analog-digital converter module to be fed back via a calibration unit to an adjustable amplifier of the analog-digital converter module. Amplification can therefore be adjusted as a function of the amplitude and phase responses in the useful band.

The invention is based on the generic method according to claim 19, in that the frequency signal is fed to a first signal path, the frequency signal is fed to a second signal path, that an analog signal processing occurs in the first signal path, and that a digital signal processing occurs in the second signal path, that specific frequency regions are selectively suppressed during digital signal processing, and that a signal resulting from analog signal processing is combined with a signal resulting from digital signal processing. The advantages of the device according to the invention are implemented by this method.

A signal is preferably digitized in the second signal path, the digitized signal is fed to an FIR filter and the filtered signal is fed to a digital-analog converter. In this manner, a causal complementary filter is made available by the power limitation module, whose filter part is designed digitally. The useful signal is suppressed by means of an FIR filter on the second signal path, while the adjacent channels are processed with the highest possible SNR. The filtered signal is then fed for further processing to a digital analog converter.

A power adjustment, a delay adjustment and an si(x) compensation are preferably performed in the FIR filter. Consequently, the digital signal can be processed so that a signal is subsequently formed by combination with the analog signal supplied via the first signal path, in which the useful band is transmitted unaltered, while the adjacent channels are suppressed.

It is particularly preferred that the FIR filter be operated at the scanning rate of the converter. Processing can therefore occur without a scanning rate reduction.

A signal is preferably delayed in the first signal path to the extent that corresponds to the total delay of the converter and the FIR filter of the second signal path. This ensures that the two signal paths are adapted to each other for purposes of subsequent combination.

It is particularly preferred that the signal resulting from digital signal processing be subtracted from the signal resulting from analog signal processing. The resulting signal therefore has an almost unaltered useful band, while the adjacent channels are suppressed.

The signal resulting from subtraction is preferably fed to an analog digital converter module. The actual analog digital conversion therefore occurs based on an input signal, in which the interfering adjacent channels are suppressed.

It is useful if the input frequency signal is preprocessed in analog fashion. In this manner, the analog input signal can be attenuated by analog preprocessing to the extent that the converter is not overridden on the second signal path. This is advantageous, since noise develops from the converter on the second signal path that is uncorrelated to the original signal and therefore cannot be suppressed. The power density of this noise amount must consequently be as small as possible (high SNR of the adjacent channels).

It is particularly useful if a calibration signal is fed to the input frequency signal. This calibration signal, which lies “outside” of the useful signal, is evaluated in the digital part (modem) behind the analog-digital converter module. Regulation of the digital delay can occur on this basis, so that suppression of the calibration signal is maximal. Since there is a possibility of adjusting the delay adaptively in the digital part, for example by incorporating delay elements, there is no need for the analog part to absolutely adjust the delay. As long as this merely lies on the same order of magnitude, it is possible to tune the first signal path and the second signal path to each other. However, it must be kept in mind that the group delay of the analog delay is constant over the entire frequency region of interest.

With reference to another practical example, it is useful that an output signal of an analog digital converter in the second signal path is fed to a third signal path that implements an equivalent channel with a complex mixer and an FIR filter, in which the scanning rate is reduced. Because of this, a band-stop filter of the useful band can be dispensed with on the second signal path. In this manner, the filter requirements on the FIR filter can be drastically reduced. Accordingly, it is sufficient if the analog delay element performs only a very much smaller delay, which lies lower by a factor of about 16 than in the variant with the band-stop filter. The FIR filter on the second signal path therefore carries out, for example, only an si(x) compensation, a delay adjustment and a power adjustment.

Advantageously, the output signal of the analog-digital converter module is fed to a fourth signal path having a complex mixer and an FIR filter, in which the scanning rate is reduced. The output signal of the analog-digital converter module is therefore adapted to the signal of the third signal path.

An output signal of the digital signal path is usefully combined with an output signal of the fourth signal path. By the transition to an equivalent complex low-pass signal and the subsequent combination of the third signal path and the fourth signal path, a scanning rate reduction by a factor of 8 can therefore be carried out.

It is preferred that the output signal of the analog-digital converter module be fed back via a calibration unit to at least one FIR filter. Amplification can therefore be adapted as a function of the amplitude and phase responses in the useful band.

It is also preferred that the output signal of the analog-digital converter module be fed back via a calibration unit to an adjustable amplifier of the analog-digital converter module.

The invention is based on the surprising finding that a power limitation in channels adjacent to a useful channel can be achieved by a variable filter. This filter has a fixed analog part, for example, a delay element, and a variable digital part that can be adapted to the frequency of the useful channel. Because of this, it is no longer necessary to develop channel-specific RF modules in order to tune the filter to the special frequencies of the useful channels. In particular, in DMS frequency bands that are divided among several operators, the invention therefore offers significant advantages.

### DRAWINGS

The invention is now explained with reference to the accompanying drawings.

FIG. 1 shows a circuit diagram of a first variant of the invention;

FIG. 2 shows a spectral density distribution with respect to the filter characteristics of a band-stop;

FIG. 3 shows a spectral density distribution with respect to the filter characteristics of a causal complementary band-stop filter;

FIG. 4 shows a spectral density distribution at the input of a power limiter;

FIG. 5 shows a spectral density distribution at the input of an analog adder;

FIG. 6 shows a spectral density distribution at the input of an analog-digital converter module;

FIG. 7 shows an FIR implementation by means of a filter bank;

FIG. 8 shows a spectral density at the input of an analog-digital converter module in the minimum load scenario;

FIG. 9 shows embedding of a device according to the invention in an overall system;

FIG. 10 shows a circuit diagram of another variant of the invention;

FIG. 11 shows a power density distribution at the input of an analog-digital converter for the maximum load scenario;

FIG. 12 shows a power density distribution at the input of an analog-digital converter for the minimum load scenario;

FIG. 13 shows a power density distribution with respect to consideration of a jitter noise power.

### DESCRIPTION OF PREFERRED VARIANTS

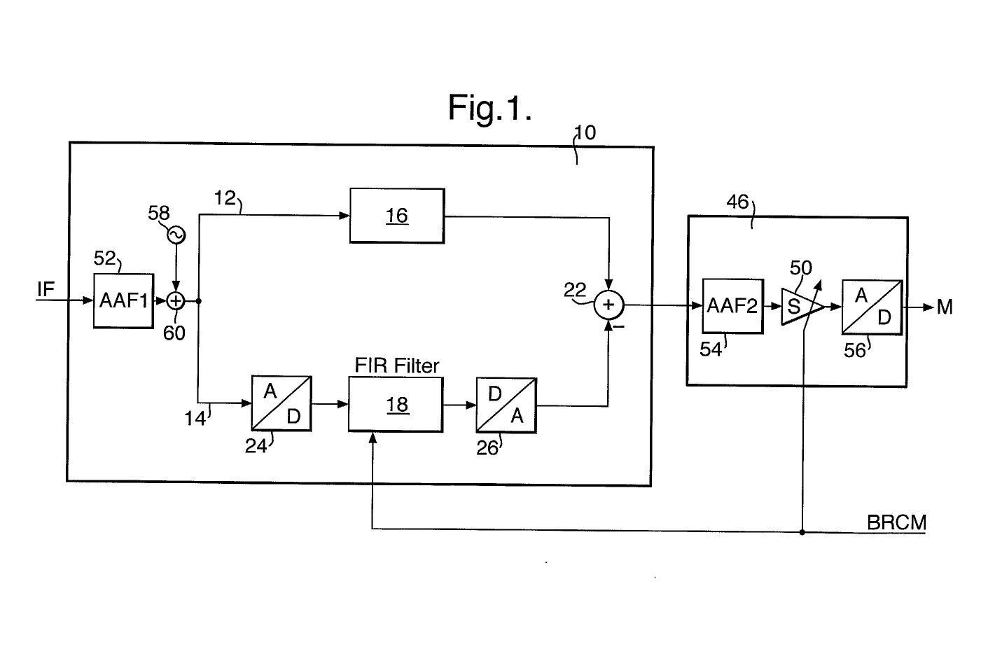

FIG. 1 shows a circuit diagram of a device according to the invention. A power limiter 10 includes a first signal path 12 and a second signal path 14. The first signal path 12 has an analog delay element 16. The second signal path 14 comprises an analog-digital converter 24, an FIR filter 18 and a digital-analog converter 26. In the present drawing, as in other circuit diagrams of the present patent application, examples of specifications and possible types of employed components are mentioned. The power limiter 10 also has an analog adder 22 at its output. At the input of the power limiter 10, an element is situated for analog preprocessing 52, as well as a mixer 60, which receives a calibration signal 58, in addition to the preprocessed input signal. Behind the power limiter 10, there is an analog-digital converter module 46. It contains an element for analog preprocessing 54, an adjustable amplifier 50 and an analog-digital converter 56. The output signal of the analog-digital converter is fed to modem M. Signal paths from a broadcast modem BRCM are also shown, which lead to the adjustable amplifier 50 and the FIR filter 18.

An intermediate frequency input signal IF is fed to the element for analog preprocessing 52. It is mixed in a mixer 60 with a calibration signal 58. The output signal of mixer 60 is divided to a first signal path 12 and a second signal path 14. In the second signal path 14, digitization occurs in the analog-digital converter 24. Suppression of the desired useful channel occurs in the FIR filter 18, along with a delay adjustment, a power adjustment and an si(x) compensation. The output signal of the FIR filter 18 is fed to a digital analog converter 26. The signal of the first signal path 12 is fed to an analog delay element 16, whose delay is tuned to the total delay of the second signal path 14. The first signal path 12 and the second signal path 14 are finally fed to an analog adder 22, in which the signal of the second signal path 14 is subtracted from the signal of the first signal path 12. Consequently, the secondary bands are suppressed, while the useful band passes through the power limiter 20 almost unaltered. The signal so filtered is fed to an element for analog preprocessing 54 in the analog-digital converter module 46, then amplified in the adjustable amplifier 50 and finally fed to an analog-digital converter 56 for final digitization. The output signal of the analog-digital converter is fed to modem M. Both the adjustable amplifier 50 and the FIR filter 18 are adjustable via a broadcast modem BRCM.

The modular power limiter 10 so implemented is a causal complementary filter, whose delay element is designed analog, and whose filter part is digital. In the lower branch, the useful channel is suppressed by means of an FIR filter 18. The adjacent channels are processed with the highest possible SNR. The digital-analog converter signal is subtracted in the analog adder 22 from the delayed analog original signal, so that the adjacent channels are suppressed and the useful channel is unaffected.

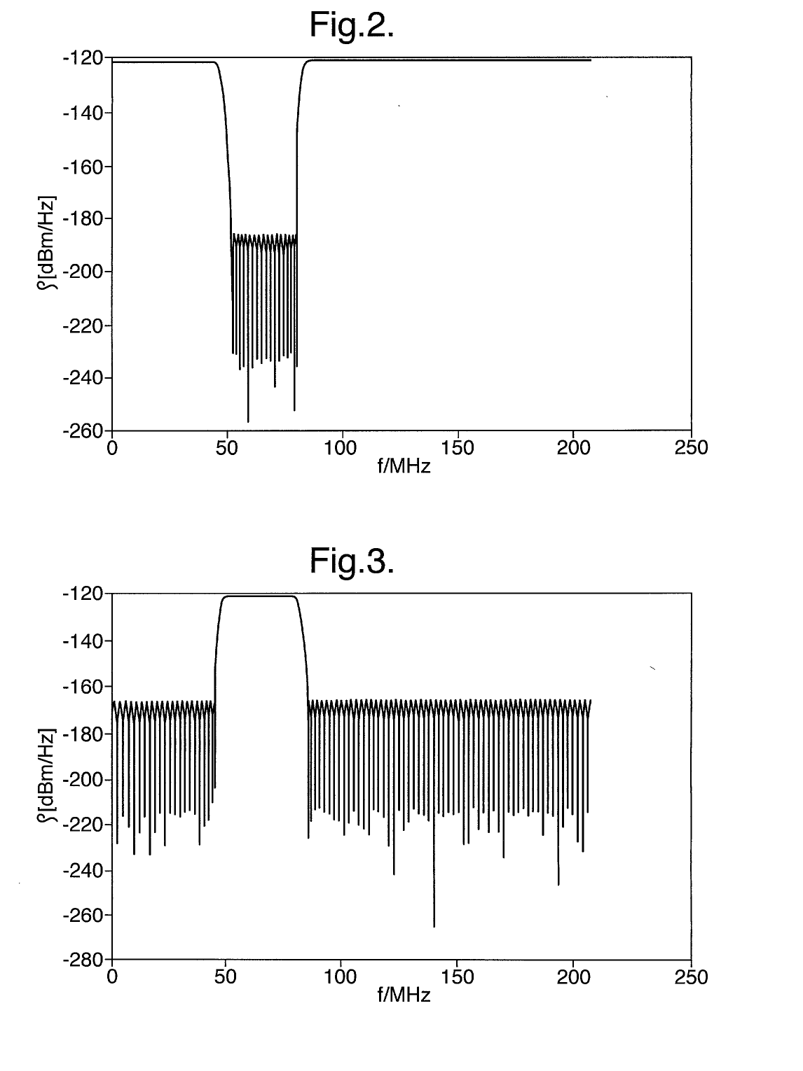

The transmission characteristics of the FIR filter 18 for suppression of the useful channel are shown in FIG. 2.

FIG. 3 shows the overall filter characteristics (complementary filter to FIG. 1) from the input to the output of the modular power limiter 10. The useful band is transmitted unaltered and the adjacent channels are suppressed.

Two criteria are important in dimensioning this special arrangement:

Degradation of the SNR in the useful channel must be as small as possible, i.e., the noise power density of the FIR branch in the useful channel at the input of the adder must be significantly smaller than the noise power density of the original signal.

The SNR in the adjacent channels at the input of the adder should be as large as possible.

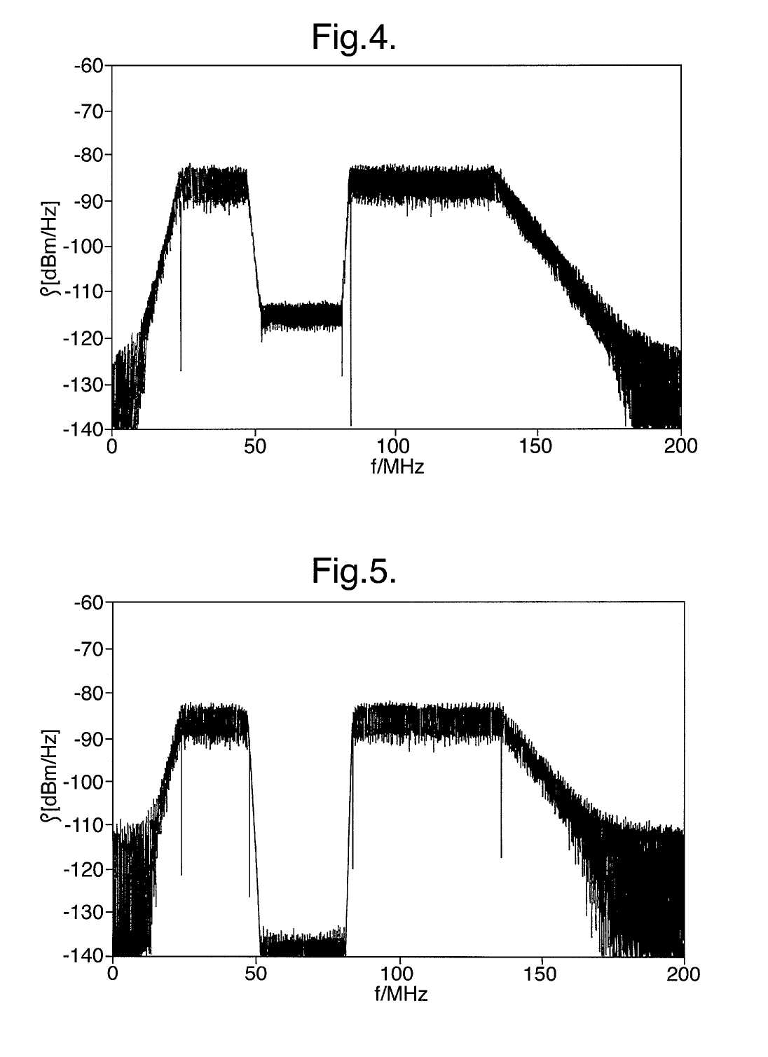

FIGS. 4, 5 and 6 show the spectra at different points of the arrangement. A simulation with the following parameters was conducted:

Four 28 MHz DMS channels, in which the second channel is assumed to be useful channel,

BNR=47 dB, i.e., the three adjacent channels lie 30 dB above the useful channel (SNR=17 dB),

S=25 dB, i.e., the analog signal must be amplified before the actual analog-digital conversion by 25 dB, in order to achieve the required SNR,

Analog-digital converter in the FIR branch: F_ADC=7 nominal bits at 414.8 MHz scanning frequency,

Digital-analog converter in FIR branch: F_DAC=11 nominal bits at 414.8 MHz scanning frequency,

Use of an ideal analog delay element.

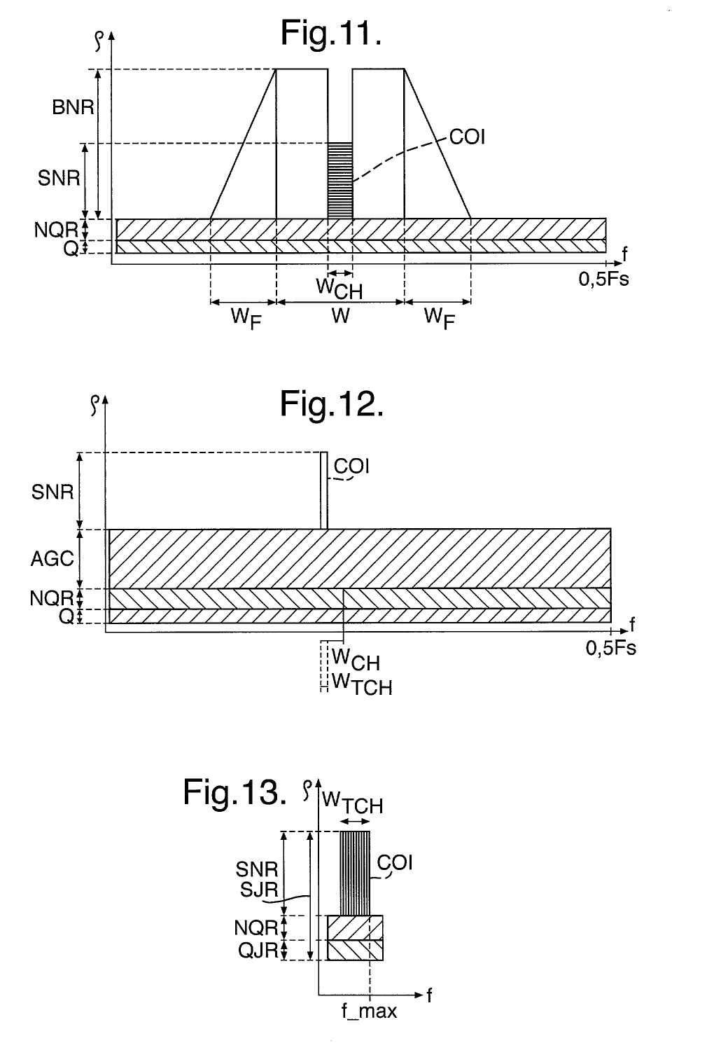

FIG. 4 shows the input spectrum, which is comparable to the model from FIG. 11. The lower horizontal line indicates the density of the quantization noise of the analog-digital converter of the converter module (ADC=7 bits). The analog preprocessing scales the signal, so that the analog-digital converter in the FIR branch is not overridden. The SNR in the useful channel lies at SNR≅0 dB at this setting.

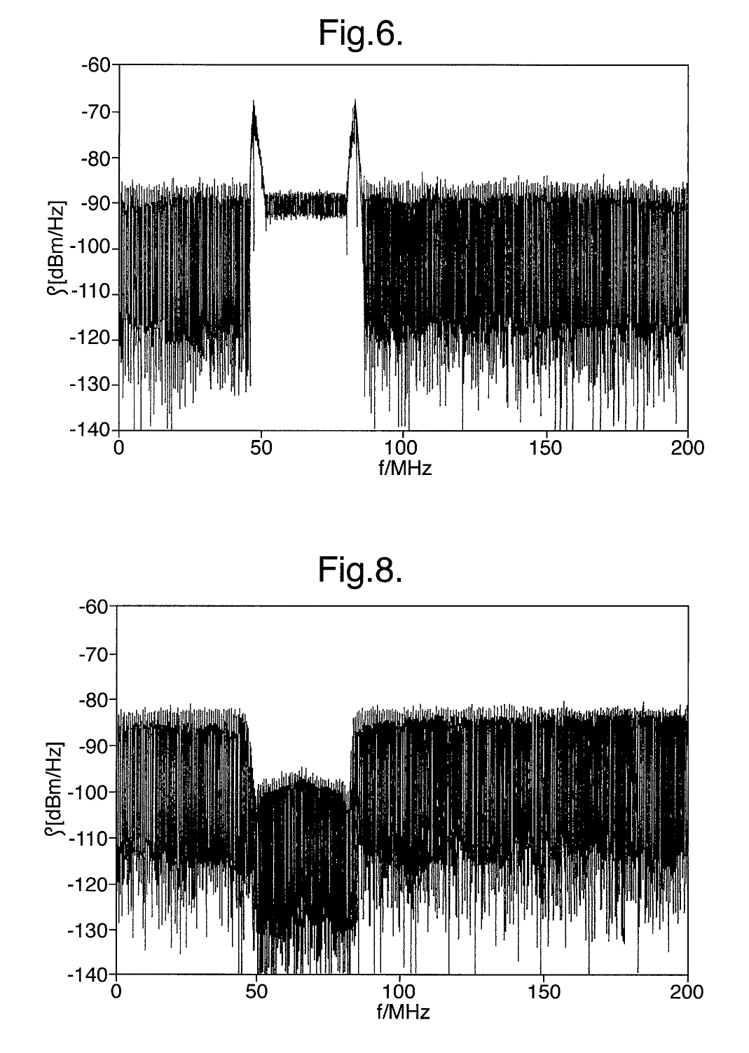

In FIG. 6, the spectrum at the input of the adder (FIR branch) is shown. The noise power density in the useful channel is about 20 dB below the noise power density of the original signal, so that the useful channel SNR degradation is small.

The spectrum at the input of the analog-digital converter of the converter module after amplification is shown in FIG. 6. The adjacent channels now contain essentially the amplified converter noise. The two spikes to the left and right of the useful channel contain the unsuppressed adjacent channel signal power, owing to the FIR filter flanks of finite steepness.

The power of the signal according to FIG. 6 is now so small that the converter of the converter module is not overridden.

A problem with respect to the arrangement according to the invention consists of efficiently suppressing the signal power directly next to the useful channel. For this reason, the FIR filter should have the steepest possible filter flank, which leads to a high gradient (N>150). Moreover, the filter should process at the scanning rate of the converter, i.e., without a scanning reduction. With respect to the problem of scanning rates, it can be useful to implement the FIR filter by means of a filter bank.

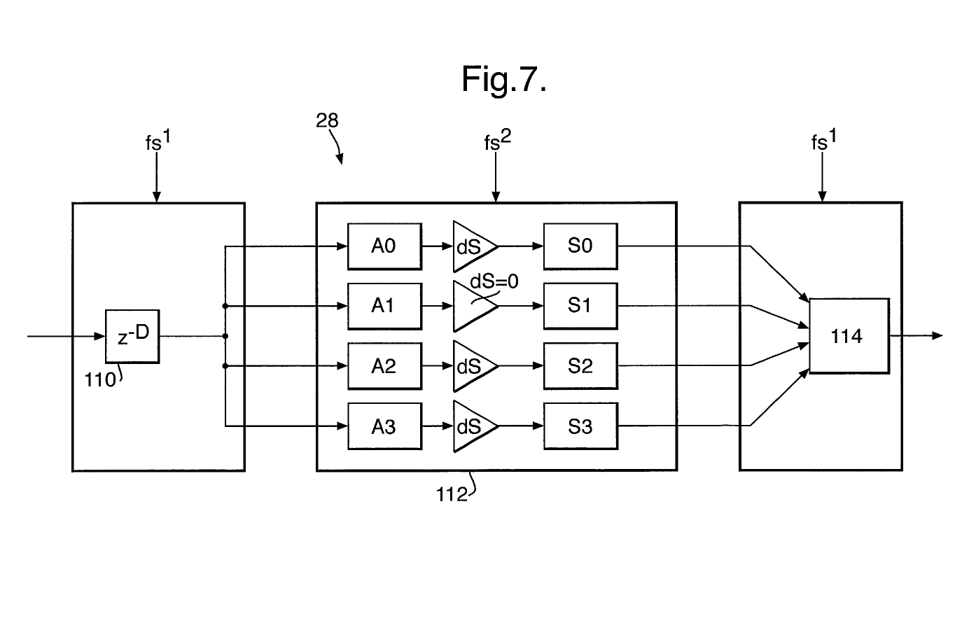

FIG. 7 is referred to for description of this solution. It shows an arrangement for crude delay adjustment 110 and an arrangement 112 for amplification adjustment, for the channel configuration and for the fine delay adjustment. The latter arrangement 112 comprises four analysis filters A0, A1, A2 and A3, corresponding amplifiers dS and synthesis filters S0, S1, S2 and S3. An adder 114 is also provided, to which the signals of the synthesis filters S0, S1, S2 and S3 are fed.

At scanning frequencies up to 200 MHz, there is a possibility of directly implementing the FIR filter, at scanning frequencies around 400 MHz, this is not possible at present. The solution in FIG. 7 offers an alternative to this, which is based on a “perfect reconstruction (PR)” filter bank. Each analysis filter processes a band-pass FIR filter for a 28 MHz channel, the scanning rate is simultaneously reduced, so that the filter is calculated at 1/4 of the scanning rate, for example. The sub-band of the useful channel is tuned out (line 1 in FIG. 7), so that the band-stop characteristic of FIG. 2 is produced. The other sub-bands are multiplied by a correction value to compensate for possible amplification mismatches in the two lines. By using different analysis/synthesis coefficient sets and by using different phases of the downward scanned signal, a fine adjustment of the delay can be performed.

After synthesis filtering, addition of the sub-band signals with the high scanning frequency occurs.

A fine adjustment of the delay could also occur by controlling the digital-analog scanning phase by the digital part.

The spectrum at the input of the analog-digital converter for the minimum load scenario is shown in FIG. 8. As already mentioned, the signal power must be increased during small channel movement under some circumstances, in order to avoid SNR degradation in the useful channel. The suppression module can be used for this scenario as a dither generator. According to the scenario of FIG. 12, a signal that carries only a traffic channel with a bandwidth of 80 kHz is assumed as analog input signal. It is clear that the amplified converter noise of the suppression module guarantees adequate control. No control of the converter amplifier as a function of occupied channels is therefore required.

The arrangement according to FIG. 1 is described analytically below: by means of examples, the essential feasibility is demonstrated. The basis for the following examples are the following components:

| Component | Type | Manufacturer | Properties |
|---|---|---|---|
| AD-Converter | TS8387 | Thomson | Scanning rate: 500 MHz |
| | | | Number of nominal bits: 8 |
| DA-Converter | MB86061 | Fujitsu | Scanning rate: 400 MHz |
| | | | Number of nominal bits: 12 |
| FPGA | XCV200 | XILINX | 16 × 16 bit multiplications |
| | | | with 130 MHz |

In the next two sections, the useful channel and adjacent channel are treated separately and dimensioning of the system parameters derived from them.

Useful Channel

The decisive parameter is the degradation Δ of SNR for the useful channel over the entire processing chain, i.e., up to the output of the converter module. This degradation can be determined by equation (12).

The relation considers the noise of the two analog-digital converters and the digital-analog converter. The noise of the converter amplifier is likewise disregarded, as is the noise caused by the finite accuracy of signal processing. The latter can be minimized by appropriate effort.

Δ=10·lg(1+N_{FIR}^{S}+N_{Converter}^{S})

where

$${N}_{Converter}^{S} = {10}^{\frac{S - N Q R}{10}} \cdot {2}^{2 A D C} \cdot ( {2}^{- 2 F\_ADC} \cdot {10}^{\frac{F\_ATT}{10}} + {2}^{- 2 F\_DAC} ) \\ {N}_{FIR}^{S} = {10}^{\frac{S N R - F\_ATT}{10}} {+}^{\frac{N Q R}{10}} \qquad ( 12 )$$

(NQR, ADC and S are dependent on each other)

SNR=Signal-to-noise ratio of the useful channel in dB

NQR=Noise-to-quantization noise ratio in dB

S=Value of the amplifier (>0) in dB

ADC=Number of effective bits of the final analog digital converter

F_ADC=Number of effective bits of the analog-digital converter in the FIR path

F_DAC=Number of effective bits of the digital-analog converter in the FIR path

F_ATT=Attenuation of the band-stop filter in the FIR path

The noise contribution N^{S}_{converter} of the converter is now further investigated. Since the signal power was reduced by S dB by the suppression module, the following applies with (2) for avoidance of saturation:

$$B N R - S = 10 \cdot 1 g ( \frac{3 \cdot {2}^{2 ( ADC - 1 )} \cdot {10}^{\frac{C r + N Q R}{10}} - \frac{{W}_{CH}}{{f}_{s}} \cdot {10}^{\frac{S N R}{10}} + \frac{2 \cdot {W}_{F} + W}{{f}_{s}} - \frac{1}{2}}{\frac{{W}_{F} + W - {W}_{CH}}{{f}_{s}}} ) \qquad ( 13 )$$

The following is obtained:

$${N}_{Converter}^{S} = {10}^{\frac{BNR - NQR}{10}} \cdot \frac{\frac{{W}_{F} + W - {W}_{CH}}{{f}_{S}} ( {2}^{- 2 F\_ADC} \cdot {10}^{\frac{F\_ATT}{10}} + {2}^{- 2 F\_DAC} )}{0.75 \cdot {10}^{\frac{Cr + NQR}{10}} - {2}^{- 2 ADC} ( \frac{{W}_{CH}}{{f}_{s}} \cdot {10}^{\frac{SNR}{10}} - \frac{2 \cdot {W}_{F} + W}{{f}_{s}} + \frac{1}{2} )}$$

The resolution of the analog-digital converter F_ADC is not critical, since the quantization noise is weighted with attenuation of the FIR filter. The resolution of the digital-analog converter is decisive.

Where:

BNR=47 dB

SNR=17 dB

ADC=7 bit

F_ADC=7 bit

F_DAC=11 bit

F_ATT=60 dB

NQR=13 dB

Cr=10 dB

W=112 dB

W_CH=28 MHz

W_F=28 MHz

f_s=414.8 MHz

we get

N^{S}_{converter}=0.046

as noise contribution of the converter.

In the noise contribution of the FIR filter, the first term is non-critical. With SNR=17 dB and F_ATT=60 dB, we get a negligibly small amount for N^{S}_{converter}. The quantity NQR is decisive here.

Overall, we get:

N_{FIR}^{S}=0.00005+0.05≈0.05

as noise contribution of the FIR filter.

The degradation of the useful signal from the input of the suppression module to the output of the converter module for this numerical example is:

Δ=10·lg(1+0.046+0.05)=0.4 dB

Adjacent Channels

The decisive criterion is suppression of the adjacent channel frequencies. It can be calculated by equation (14) as a function of frequency.

This relation considers the noise of the converter, the property of the FIR filter and the inaccuracies in the analog part (different signal delays in the digital and analog branch). The noise caused by the finite accuracy of signal processing, as well as the amplifier noise, were not considered (see above).

A suppression of the adjacent channelsof at least 20 dB is sought (Example 2). The requirements are calculated for this value:

$$Sup ( f ) = - 10 \cdot 1 g ( {10}^{\frac{CF\_ATT}{10}} + {N}_{Converter}^{P} + {N}_{Analog} ( f ) )$$

with

$${N}_{Converter}^{P} = {10}^{- \frac{BNR - S}{10}} \cdot {10}^{\frac{NQR}{10}} \cdot {2}^{2 ADC} \cdot ( {2}^{- 2 F\_ADC} + {2}^{- 2 F\_DAC} ) \qquad ( 14 )$$

N_{Analog}(f)=2·(1−cos (2πf|τ|))

where

BNR=Blocking-to-noise ratio of the adjacent channels in dB

NQR=Noise-to-quantization noise ratio in dB

S=Value of the amplifier (>0) in dB

ADC=Number of effective bits of the final analog-digital converter

F_ADC=Number of effective bits of the analog-digital converter in the FIR path

CF_ATT=Attenuation of complementary band-stop filter ( [symbol] ripple of the band-stop)

τ=Signal delay difference in the adder between the two paths in (sec)

Using (13), we obtain for the contribution N^{P}_{converter}:

$${N}_{Converter}^{P} = {10}^{- \frac{NQR}{10}} \cdot \frac{\frac{{W}_{F} + W - {W}_{CH}}{{f}_{S}} \cdot ( {2}^{- 2 F \_ ADC} \_ {2}^{- F \_ DAC} )}{0.75 \cdot {10}^{- \frac{Cr + NQR}{10} - {2}^{- 2 ADC}} ( \frac{{W}_{CH}}{{f}_{S}} \cdot {10}^{\frac{SNR}{10}} - \frac{2 \cdot {W}_{F} + W}{{f}_{S}} + \frac{1}{2} )}$$

The noise of the AD-DA converter chain reduces the attainable SNR in the adjacent channels and therefore their suppression at the output of the adder.

With realistic values:

ADC=7 bit

F_ADC=7 bit

F_DAC=11 bit

SNR=17 dB

NQR=13 dB

Cr=10 dB

W=112 MHz

W_CH=28 MHz

W_F=28 MHz

f_s=414.8 MHz

we get

N^{P}_{converter}=0.00023.

Whereas resolution of the analog-digital converter in the FIR branch was almost meaningless for the useful channel, the resolution is directly involved here. On the other hand, the resolution of the digital-analog converter could be reduced here.

This is a very critical contribution. This term is frequency-dependent and the requirements on the delay accuracy increase with signal frequency. In order to achieve the required attenuation of 20 dB at the band end (fₘₐₓ=136 MHz), the condition (equation 14)

|τ|<0.12 ns

must be met.

At the band start (for example, f=24 MHz), the condition is less strict:

|τ|<0.68 ns

With these values and CF_ATT=45 dB (FIG. 3), we obtain as minimal attainable attenuation of these secondary channels:

Sup(f)>10.1 g (0.00003+0.00023+0.01)≈20 dB for fε[24.136 MHz]

It is clear that the mismatch decisively determined the level of suppression of the secondary channels.

The requirements on the timing jitter are now determined by the adjacent channels. Since a signal-to-noise ratio of Sup(f)=20 dB lies at the input of the adder, the requirement

SJR−Sup(f)>10 dB.

must be met.

The condition for the converter module is like equation (9) in Example 2:

SJR−SNR>NQR+10 dB.

This last condition is certainly stricter, so that the requirement on timing jitter for the overall arrangement amounts to

σ≦18.5 psec.

Overall, the following requirements are imposed on the analog part:

The analog delay element must accomplish a constant group delay on the order of 250 ns over the frequency range of interest. The permitted deviations reach a maximum of ±0.68 ns at low frequencies to a maximum of ±0.12 s at high frequencies.

The analog adder must operate free of distortion over the entire frequency range of interest. It should be noted that the digital-analog-converted signal possesses much higher bandwidth than the original signal.

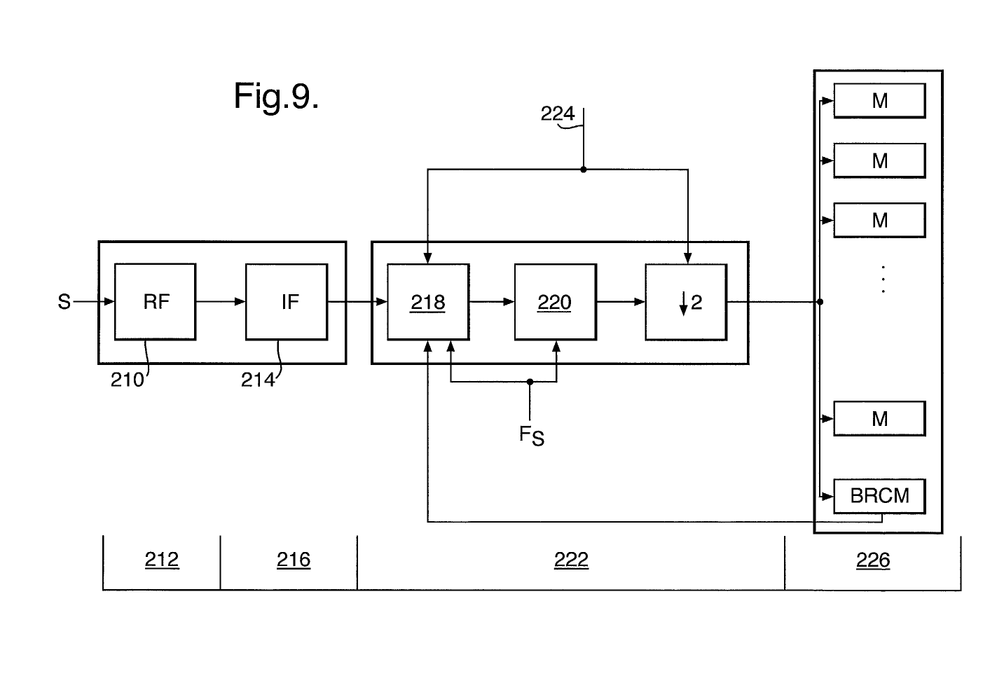

FIG. 9 shows a possible embedding of the invention in an overall system. The functional groups are marked on the lower edge of the depiction by reference numbers. Here, 212 denotes four different RF modules, 216 two different IF modules, 222 a converter of the analog/digital type and 226 a modem of the digital type.

A signal S is fed to RF module 210. Its output signal is fed to an IF module 114. The output of the IF module is fed to an element for suppression outside of channel 218. Its output signal leads to a converter module 220. The resulting 207.4 MHz signal is distributed to the modems M. The central broadcast modem BRCM processes the calibration signal and generates corresponding adjustment information for the digital part of the suppression module.

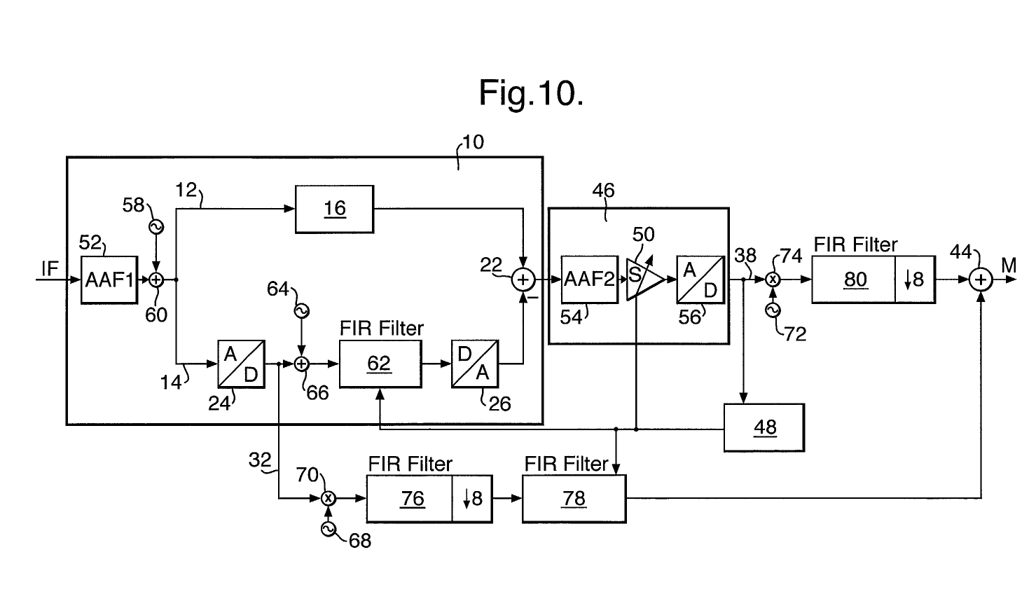

Another practical example of the invention is depicted in FIG. 10. Elements that correspond to those depicted in FIG. 1 are marked with the same reference numbers. In contrast to the variant according to FIG. 1, an FIR filter 62 is provided in the power limiter 10; this filter performs no band-stop filtering of the useful band. A third signal path 32 is additionally provided, which branches off behind the analog-digital converter 24 of the second signal path 14. This includes a mixer 70, in which the branched signal is mixed with an additional signal 78. The initial signal of the mixer is fed to an FIR filter 76. A scanning rate reduction is performed. The resulting output signal is fed to an additional FIR filter 78. Behind the analog/digital converter 46, a fourth signal path 38 is present. Here again, the signal is mixed with another signal 72 in a mixer 74. The output signal of the mixer is fed to an FIR filter 80, a scanning rate reduction also being conducted here. The output signal on the fourth signal path 38 and the output signal on the second signal path 32 are fed to an adder 44. Its output signal is sent to modem M.

Since a band-stop filtering of the useful band is dispensed with in the FIR filter 62, the filter requirements on the FIR filter 62 could be drastically reduced. The analog delay element 16 must therefore implement a much smaller delay, which is lower, for example, by a factor of about 16. However, the requirements on digital final processing rise because of this. It must also be kept in mind that accurate knowledge of the conditions (amplitude and phase responses in the useful band) between the digital-analog converter and the subsequent analog-digital converter is necessary.

After the first analog-digital converter, an si(x) compensation, as well as a delay and power adjustment, are carried out for the four 28 MHz bands, as in previous systems. A band-stop filtering of the useful band is not necessary. Strong signal fractions in the useful band that lie well above the quantization noise of the digital-analog converter are therefore possible behind the digital-analog converter. These interference fractions must therefore be compensated behind the second analog-digital converter. For this purpose, an equivalent channel is implemented digitally. Since only the useful band is of interest, a scanning rate reduction by a factor of 8 can be carried out by transition to the equivalent complex low-pass signal.

In the present variant, the following problems must be considered, in particular:

An analog delay element that has a constant group delay on the order of 15 ns is necessary over the frequency range of interest from, say, 20 to 150 MHz. If the delays in both branches do not match, the filter effect is reduced. The filter effect is also reduced if the amplification is different in the branches.

An si(x) compensation filter is supposed to process at the converter scanning rate (414.8 MHz).

The signal fractions that go through the digital-analog converter and distort the useful signal in the adder must be compensated by digital final processing. For this purpose, a very precise knowledge of the amplitude response and delay is necessary. Digital implementation must occur finely tuned accordingly.

The analytical description and dimensioning of the variant presented here is as follows:

The decisive parameter is the degradation Δ of the SNR for the useful channel over the entire processing chain, i.e., to the output of the converter module. This degradation can be determined by equation (15).

For a simple calculation and presentation, it is assumed that the system of si(x) compensation, digital-analog converter, adder, AAF2, amplifier and analog-digital converter implement an ideal frequency response with amplification S in the useful band, and all deviations are described by matching errors in the equivalent channel.

In the calculations, the noise of the two analog-digital converters and of the digital-analog converter is considered, but not the noise of the converter amplifier

$$Δ = 10 \cdot lg ( 1 + {N}_{Model}^{S} + {N}_{DA}^{S} + {10}^{\frac{NQR}{10}} )$$

with

$${N}_{DA}^{S} = {10}^{\frac{S - NQR}{10}} \cdot {2}^{2 ( ADC - F \_ DAC )} \\ \begin{matrix}{N}_{Model}^{S} = ( {10}^{\frac{S - NQR}{10}} \cdot {2}^{2 ( ADC - F \_ ADC )} - {10}^{\frac{SNR}{10}} ) \cdot \\ ( 1 - 2 \cdot {10}^{\frac{δ}{20}} \cdot cos ( 2 π f ϵ ) + {10}^{\frac{δ}{10}} )\end{matrix} \qquad ( 15 )$$

where

SNR=Signal-to-noise ratio of the useful channel in dB

NQR=Noise-to-quantization noise ratio in dB

S=Value of the amplifier (>0) in dB

ADC=Number of effective bits of the final analog-digital converter

F_ADC=Number of effective bits of the analog-digital converter in the FIR path

F_DAC=Number of effective bits of the digital-analog converter in the FIR path

F_ATT=Attenuation of the band-stop filter in the FIR path δ=Mismatch of the amplitude response in the equivalent channel in dB

ε=Signal delay error of the equivalent channel

The noise contribution N^{S}_{DA} of the digital-analog converter is now further investigated. Since the signal power was reduced by the suppression module by S dB, the following applies, using (13):

$${N}_{DA}^{S} = {10}^{\frac{BNR - NQR}{10}} \cdot \frac{\frac{{W}_{F} + W - {W}_{CH}}{{f}_{S}} \cdot ( {2}^{- 2 F \_ DAC} )}{0 , 75 \cdot {10}^{\frac{Cr + NQR}{10}} - {2}^{- 2 ADC} ( \frac{{W}_{CH}}{{f}_{S}} \cdot {10}^{\frac{SNR}{10}} - \frac{2 \cdot {W}_{F} + W}{{f}_{S}} + \frac{1}{2} )}$$

The resolution of the digital-analog converter is decisive here.

Where:

BNR=47 dB

SNR=17 dB

ADC=7 bit

F_ADC=7 bit

F_DAC=11 bit

NQR=13 dB

Cr=10 dB

W=112dB

W_CH=28 MHz

W_F=28 MHz

f_s=414.8 MHz

one gets

N^{S}_{DA}=0.043

The resolution of the analog-digital converter F_ADC is non-critical if the noise power density caused by this is smaller than the useful signal power density.

With δ=0.05 dB and ε=20 ps, we get for f=136 MHz and the above values

N^{S}_{Model}=0.020

With 10 NQR/10=0.05, the degradation for this numerical example

Δ=10. lg(1+0.020+0.043+0.05)=0.47 dB

For ⊖=10 ps, the degradation is reduced to Δ=0.42 dB.

The power in the useful band is insignificant for the suppression capability, since the adjacent channels can have the significantly higher power. If this is not true, then there is no suppression problem.

For the suppression capability of the adjacent channels, equation (14) therefore also applies.

For the requirements on the timing jitter, the timing jitter in the digital-analog converter is again decisive.

For calculation of the admissible timing jitter, it must be kept in mind that the quantization noise of the first analog-digital converter can be on the order of the signal level in the useful band and therefore must be included in the calculation (first addend beneath the square root).

$${σ}_{j} \leq \frac{{10}^{- \frac{SJR - SNR}{20}}}{2 \cdot π \cdot f \cdot \sqrt{{10}^{- \frac{S - NQR}{10}} \cdot {2}^{2 ( ADC - F \_ ADC )} + {10}^{\frac{SNR}{10}}}}$$

SNR=Signal-to-noise ratio in dB

SJR=Signal-to-jitter ratio in dB

NQR=Noise-to-quantization noise ratio in dB

S=Value of the amplifier (>0) in dB

ADC=Number of effective bits of the final analog-digital converter

F_ADC Number of effective bits of the analog-digital converter in the FIR path

With the known numbers and the condition

SJR−SNR>NQR+10 dB

we obtain the requirement on the timing jitter as:

σ_{J}≦10 psec

Overall, the following requirements are imposed on the analog part:

The analog delay element must implement a constant group delay on the order of 15 ns over the frequency range of interest. The permitted deviations range from a maximum ±0.68 ns at low frequencies to a maximum of ±0.12 ns at high frequencies.

The analog adder must operate free of distortion over the frequency range of interest. It should be noted that the digital-analog converted signal has a very much higher bandwidth than the original signal.

After digital final processing, a 28 MHz channel is available as complex base band signal. An additional three 28 MHz bands can be processed without additional converters. The digital final processing need only be multiply installed for this purpose.

The features of the invention disclosed in the aforementioned description, in the drawing and in the claims can be significant both individually and in any combination for implementation of the invention.

1. Device for processing frequency signals with a power limiter (10), characterized by the fact
that the power limiter (10) has a first signal path (12),
that the power limiter (10) has a second signal path (14),
that the first signal path (12) has means (16) for analog signal processing,
that the second signal path (14) has means (18) for digital signal processing,
that the means (18) for digital signal processing have means for selective suppression of specific frequency regions, and
that an output of the first signal path (12) and an output of the second signal path (14) are connected to the means (22) for combining the signals.

2. Device according to claim 1, characterized by the fact that the second signal path (14) has an analog-digital converter (24), and FIR filter (18) and a digital-analog converter (26).

3. Device according to claim 1 or 2, characterized by the fact that a power adjustment, a delay adjustment and an si(x) compensation can be carried out in the FIR filter (18).

4. Device according to one of the preceding claims, characterized by the fact that the FIR filter (18) has steep filter flanks.

5. Device according to one of the preceding claims, characterized by the fact that the FIR filter (18) operates at the scanning rate of the converters (24, 26).

6. Device according to one of the preceding claims, characterized by the fact that the FIR filter (18) is implemented by means of a filter bank (28).

7. Device according to one of the preceding claims, characterized by the fact that the first signal path (12) has an analog delay element (16).

8. Device according to one of the preceding claims, characterized by the fact that the analog delay element (16) has a constant group delay.

9. Device according to one of the preceding claims, characterized by the fact that the constant group delay corresponds to the total delay of the converters (24, 26) and of the FIR filter (18).

10. Device according to one of the preceding claims, characterized by the fact that the means for combining the signals have an analog adder (22).

11. Device according to one of the preceding claims, characterized by the fact that the output signal of the analog adder (22) can be fed to an analog-digital converter module (46).

12. Device according to one of the preceding claims, characterized by the fact that the input frequency signal can be fed to means (22) for analog preprocessing.

13. Device according to one of the preceding claims, characterized by the fact that a calibration signal (58) can be fed to the input frequency signal.

14. Device according to one of the preceding claims, characterized by the fact that a third signal path (32) is provided, which implements an equivalent channel digitally, in which a scanning rate reduction occurs, the third signal path (32) having a complex mixer (34) and an FIR filter (76, 78).

15. Device according to one of the preceding claims, characterized by the fact that the output signal of the analog-digital converter module (46) can be fed to a fourth signal path (38), in which a scanning rate reduction occurs, the fourth signal path (38) having a complex mixer (70) and an FIR filter (72).

16. Device according to one of the preceding claims, characterized by the fact that an output of the third signal path (32) and an output of the fourth signal path (38) are connected to means (44) for combination of signals.

17. Device according to one of the preceding claims, characterized by the fact that the output signal of the analog-digital converter module (46) can be fed back to at least one FIR filter (62, 78) via a calibration unit (48).

18. Device according to one of the preceding claims, characterized by the fact that the output signal of the analog-digital converter module (46) can be fed back to an adjustable amplifier (50) of the analog-digital converter module (46) via a calibration unit (48).

19. Method for processing frequency signals, in which a power is limited, characterized by the fact
that the frequency signal is fed to a first signal path (12),
that the frequency signal is fed to a second signal path (14),
that an analog signal processing occurs in the first signal path (12),
that a digital signal processing occurs in the second signal path (14),
that specific frequency regions are selectively suppressed in the digital signal processing, and
that a signal resulting from analog signal processing is combined with a signal resulting from analog signal processing [sic].

20. Method according to claim 19, characterized by the fact that a signal is digitized in the second signal path (14), the digitized signal is fed to an FIR filter (18) and the filtered signal is fed to the digital-analog converter (26).

21. Method according to claim 19 or 20, characterized by the fact that a power adjustment, a delay adjustment and an si(x) compensation are carried out in the FIR filter.

22. Method according to one of the claims 19 to 21, characterized by the fact that the FIR filter (18) is operated at the scanning rate of the converters (24, 26).

23. Method according to one of the claims 19 to 22, characterized by the fact that a signal is delayed in the first signal path (32) to an extent that corresponds to the total delay of the converters (24, 26) and of the FIR filter (18, 62) of the second signal path (14).

24. Method according to one of the claims 19 to 23, characterized by the fact that the signal resulting from digital signal processing is subtracted from the signal resulting from analog signal processing.

25. Method according to one of the claims 19 to 24, characterized by the fact that the signal resulting from subtraction is fed to an analog-digital converter module (46).

26. Method according to one of the claims 18 to 25, characterized by the fact that the input frequency signal is preprocessed in analog fashion.

27. Method according to one of the claims 19 to 26, characterized by the fact that a calibration signal (58) is fed to the input frequency signal.

28. Method according to one of the claims 19 to 27, characterized by the fact that an output signal of an analog-digital converter (24) in the second signal path (14) is fed to a third signal path (32) that implements an equivalent channel with a complex mixer (68) and an FIR filter (76, 78), in which the scanning rate is reduced.

29. Method according to one of the claims 19 to 28, characterized by the fact that the output signal of the analog-digital converter module (46) is fed to a fourth signal path (38) having a complex mixer (74) and an FIR filter (80), in which the scanning rate is reduced.

30. Method according to one of the claims 19 to 29, characterized by the fact that an output signal of the third signal path (32) is combined with the output signal of the fourth signal path (38).

31. Method according to one of the claims 19 to 30, characterized by the fact that the output signal of the analog-digital converter module (46) is fed back to at least one FIR filter (62, 78) via a calibration unit (48).

32. Method according to one of the claims 19 to 31, characterized by the fact that the output signal of the analog-digital converter module (46) is fed back to an adjustable amplifier (50) of the analog-digital converter module (46) via a calibration unit (48).
